(19) United States
(12) Patent Application Publication
(10) Pub. No.: US 2021/0194481 A1
(43) Pub. Date: Jun. 24, 2021

(54) DYNAMIC CAPACITIVE SENSING

(71) Applicant: AZOTEQ (PTY) LTD, Paarl (ZA)

(72) Inventors: Daniel Barend RADEMEYER, Paarl (ZA); Riaan DU TOIT, Paarl (ZA)

(21) Appl. No.: 17/273,852

(22) PCT Filed: Sep. 3, 2019
(86) PCT No.: PCT/ZA2019/050056

§ 371 Date: Mar. 5, 2021

(30) Foreign Application Priority Data
Sep. 7, 2018 (ZA) 2018/05997

(51) Int. Cl. H03K 17/955; H03K 17/96

(52) U.S. Cl. CPC H03K 17/955; H03K 2217/960735; H03K 2217/960775; H03K 17/962

(57) ABSTRACT

A capacitive sensing circuit which uses the same electrodes or conductive structure or structures to perform both self-capacitance and mutual-capacitance measurements during a self-capacitance mode and a mutual-capacitance mode respectively, wherein the mutual-capacitance measurements are used to detect user proximity and the self-capacitance measurements are used to detect user touch.

### BACKGROUND OF THE INVENTION

Capacitive sensors generally fall into two categories, namely self-capacitance sensors or mutual-capacitance sensors. The former typically measures changes in the capacitance between an electrode and the surrounding electrical earth, whereas the latter measures changes in the capacitance between a transmitter and receiver electrode pair.

When capacitive sensors are used to detect user proximity, the measurements often involve fairly weak or small signals and longer detection distances than what would be encountered for touch detection. Conventionally, as is known in the art, self-capacitance sensors are preferably used for proximity detection, or to measure over longer distances, with mutual-capacitance sensors limited to touch detection, or over shorter distances.

The prior art also contains numerous teachings of using the same electrodes or conductive structure for both self-capacitance and mutual-capacitance measurements or sensing, with the mode of capacitive sensing, i.e. self- or mutual-capacitance mode, selected automatically or based on certain criteria. In prior art multi-mode capacitive sensing structures, self-capacitance measurements are preferred for proximity sensing, or to sense over longer distances, with mutual-capacitance measurements relegated to the detection of touch events.

Further, capacitive sensing applications continually face reduced space or volume availability in which they are implemented due to increased functionality of consumer electronic devices, new device types and so forth. This reduces the amount of conductive material which may be used for capacitive sensing electrodes, as well as the distance between electrodes or between electrodes and grounded conductive structures. As such, the traditional approach of using self-capacitance measurements to detect user proximity may suffer from reduced signal amplitudes and ground coupling.

Self-C (self-capacitance) based proximity detection distance is strongly influence by the distance from the sensing electrode to nearby grounded conductive structures. In addition, when a large parasitic capacitance is present in the sensing circuit, it may adversely affect said proximity distance.

For mutual-C (mutual-capacitance) based proximity sensing applications, battery powered sensing circuits often experience a reverse measurement effect when the object to be sensed is located close to sensing electrodes, for example 1 to 2 mm away, with the measured mutual-C value increasing instead of decreasing as expected. Mutual-C based measurements which rely on battery power may also experience a significant shift in signal when the sensing circuit is plugged into a utility mains powered power supply, which may influence proximity detection.

### SUMMARY OF THE INVENTION

A first exemplary embodiment of the present invention comprises a capacitive sensing circuit which may use the same electrodes or conductive structure or structures to perform both self-capacitance (self-C) and mutual-capacitance (mutual-C) measurements during a self-C mode and a mutual-C mode respectively, wherein the mutual-C measurements may be used to detect user proximity and the self-C measurements may be used to detect user touch. The capacitive sensing circuit may be partially or fully integrated in silicon or another semiconductor, as is known in the art. Said capacitive sensing circuit may switch automatically between the mutual-C and self-C modes in an alternating or other time-divisional manner, or the change in modes may be based on the one or other measured parameter or a control input provided to said circuit. The capacitive sensing circuit may further use information gathered from said self-C and mutual-C measurements to adjust either or both of said measuring modes. That is, information gathered during a self-C measurement or measurements may be used to adjust subsequent self-C measurements or to adjust subsequent mutual-C measurements, and conversely, information gathered during a mutual-C measurement or measurements may be used to adjust subsequent mutual-C measurements or to adjust subsequent self-C measurements.

Another exemplary embodiment of the present invention comprises a capacitive sensing circuit which may use distinct or different electrodes or conductive structure or structures to perform self-capacitance (self-C) and mutual-capacitance (mutual-C) measurements during a self-C mode and a mutual-C mode respectively, wherein the mutual-C measurements may be used to detect user proximity and the self-C measurements may be used to detect user touch. Said capacitive sensing circuit may switch automatically between the mutual-C and self-C modes in an alternating or other time-divisional manner, or the change in modes may be based on the one or other measured parameter or a control input provided to said circuit. The capacitive sensing circuit may further use information gathered from said self-C and mutual-C measurements to adjust either or both of said measuring modes. That is, information gathered during a self-C measurement or measurements may be used to adjust subsequent self-C measurements or to adjust subsequent mutual-C measurements, and conversely, information gathered during a mutual-C measurement or measurements may be used to adjust subsequent mutual-C measurements or to adjust subsequent self-C measurements.

In a more specific exemplary embodiment of the present invention, a capacitive sensing circuit may comprise two electrodes. During a mutual-C mode, said electrodes may be used as a transmitter (Tx) electrode and receiver (Rx) electrode pair to detect user proximity over a first distance. During a self-C mode, said electrodes or one of said electrodes may be used to detect user proximity or touch over a second distance, wherein said first distance is substantially larger than said second distance. The present invention further teaches that a capacitive sensing circuit with both a self-C and mutual-C mode as disclosed may be used to determine when an object to be detected, for example a user body part, is located at a third distance, wherein said third distance is less than said second distance. This may be especially advantageous to detect capacitive sensor saturation. For example, said third distance may be 0 mm or close to 0 mm.

An alternative exemplary embodiment of the present invention may be similar to the embodiment described in the directly preceding, but with the addition that values obtained during said self-C mode may be used to reseed, adjust or reset the mutual-C measurement circuitry of said capacitive sensing circuitry. For example, self-C measurement values may be used to determine what the baseline or reference values are for subsequent mutual-C measurements, or said self-C measurement values maybe used to determine thresholds for proximity or touch events discerned during subsequent mutual-C measurements of a mutual-C mode of the capacitive sensing circuit. The invention is not limited in this regard and includes the possibility to utilize mutual-C measurement values to reseed, adjust or reset subsequent self-C measurements.

Teachings of the present invention may also be advantageously applied to mobile consumer electronic products, for example to mobile phones. In one such application, a capacitive sensing circuit embodying the present invention may be utilized in a mobile phone, wherein mutual-C measurement values may be used to detect user proximity and subsequently to decide when to switch the display of said phone on or off. Self-C measurements made by the capacitive sensing circuit may be used to detect when said phone is placed on or close to the user's body, for example for so-called on-ear detection. The self-C measurements may also be used to determine when to reseed or reset mutual-C measurements. Reseeding a measurement may be understood to mean the following. When capacitive measurements are made, a reference value may be continually updated. Often, this process of updating the reference value may be halted due to the one or other detected event or another control parameter. Reseeding may entail restarting the reference updating process, and may involve use of currently measured capacitive sensing values to determine said reference level.

An embodiment as described may improve user proximity and touch detection in mobile consumer products such as a mobile phone, given that grounded conductive structures in such products are often located close to capacitive sensing electrodes, with required sensing distances in current state of the art products which may be as much as ten times the distance between a capacitive sensing electrode and said grounded structures.

Mobile phones, and other portable electronic products, often utilize the same conductive structure or structures as both a radio frequency (RF) antenna and as a proximity or touch electrode. These structures may typically utilize a fair amount of discrete or distributed capacitance connected to the structure to ensure acceptable RF performance. However, from a capacitive sensing viewpoint, said capacitance may form a high value parasitic load. According to the present invention, a capacitive sensing circuit embodying the presently disclosed teachings may make use of mutual-C measurements during a mutual-C mode to partially or fully prevent said parasitic load from desensitizing performance of the capacitive sensing circuit.

In yet another exemplary embodiment of the present invention, a capacitive sensing circuit with both self-C and mutual-C modes may be used in a wearable electronic device, for example an electronic bracelet or activity monitoring band. The same electrodes or conductive structures may be used by said sensing circuit for both self-C and mutual-C measurements. Or alternatively, distinct electrodes or conductive structures may be used for self-C measurements and for mutual-C measurements. Said activity band may fit loosely or snugly around a wrist of a user, as is known. According to the present invention, the capacitive sensing circuit may utilize mutual-C measurements during a mutual-C mode to detect user proximity when the band sits loosely around the user's wrist. Conversely, when the band is fastened tightly around the user's wrist or lies on or is pressed against the user's skin, self-C measurements during a self-C mode may be used to detect user proximity or touch. In such an embodiment, a long term capacitive sensing reference value may be halted or frozen, with mutual-C measurement values used to determine when to adjust, reset or reseed said reference value.

In a related exemplary embodiment, a capacitive sensing circuit as disclosed and located within a wearable consumer electronic product, for example an activity band, may additionally utilize mutual-C measurements during a mutual-C mode to detect a proximity distance or value which may be used to detect submersion of the activity band in water or another fluid.

A capacitive sensing circuit embodying the present invention may also comprise an additional capacitive sensing channel or circuitry which may be used as a reference channel to compensate for the influence of external parameters such as temperature, time and aging or noise. Said reference channel may make use of a plurality of electrodes or conductive structures. If the capacitive sensing circuit is an integrated circuit, said electrodes or conductive structures may be located internal or external to the integrated circuit packaging. In a related embodiment, the capacitive sensing circuit may use a channel or circuitry as used during said self-C mode as a reference channel.

The present invention further teaches that self-C measurements may be used by a capacitive sensing circuit as disclosed to overcome a reverse effect encountered by a mutual-C based measurement when electrodes are very close to the object to be sensed, for example of the order of 1 to 2 mm away.

By utilizing mutual-C measurements for proximity detection, as opposed to self-C measurements as is taught in the prior art, the influence of parasitic capacitance to grounded structures may be negated, as mutual-C measurements may be influenced less by these parasitics, according to the present invention.

It is further taught that self-C and mutual-C measurements may be performed for the same usage case, and wherein the different signatures of the signals thus obtained may be used to identify differences in materials located in the vicinity of sensing electrodes used for said measurements.

The present invention also teaches that the automatic decrease in mutual-C proximity detection distance which occurs when a user breaks contact, or stops to handle, a device which contains the mutual-C sensing circuit may be used advantageously. For example it may be used to determine when said user releases said device and so forth. It may also be used to trigger or release a proximity detection event for a user only, and not for inanimate matter. The inventors have also noted that a mutual-C measurement performance decrease may be closely related to said mutual-C reverse measurement effect (increase of mutual-C measurement values when a decrease is expected) being pronounced when a self-C value measured with the same sensing electrodes is relatively small.

According to the present invention, by performing both mutual-C and self-C measurements with the same electrodes or conductive structures, a unique combination of measurement values may exist when a device which houses the mutual-C and self-C sensing circuitry and electrodes is picked up from a surface. This may be used to identify the pick-up event and adjust circuitry to ensure optimal capacitive sensing.

Typical applications or embodiments of the teachings of the present invention may be found where sensing distance of self-C measurements are limited due to a large parasitic capacitive load and/or situations where a grounded structure is close to the sensing electrode, for example a screen in a mobile phone, a battery or a printed circuit board copper pour is located close to the sensing electrode being used. Some non-limiting examples of embodiments of the present invention may be found in the following: a mobile phone or tablet which utilizes conductive structures as capacitive sensing electrodes and as RF-antennas, with a high parasitic capacitance present in the capacitive sensing circuit; a watch or activity band where the distance between a grounded structure and capacitive sensing electrodes is very small; and audio earphones (in-ear and over-ear) where conductive structures used as ground references are relatively small.

### BRIEF DESCRIPTION OF THE DRAWINGS

The invention is further described by way of examples with reference to the accompanying drawings in which:

FIG. 1 shows an exemplary capacitive sensing circuit which embodies the present invention;

FIG. 2 shows a typical mobile phone with dual capacitive sensing electrodes;

FIG. 3 has plan and side views of an activity band or watch which embodies the present invention;

FIG. 4 shows two personal audio device embodiments of the invention; and

FIG. 5 shows a state diagram used to determine device state in a personal audio device.

### DETAILED DESCRIPTION OF EMBODIMENTS

Disclosure of the present invention may be further aided by a detailed description of exemplary embodiments depicted in the appended drawings. It should be understood that both the drawings and the following description are not meant to limit the present invention, but merely to clarify its disclosure.

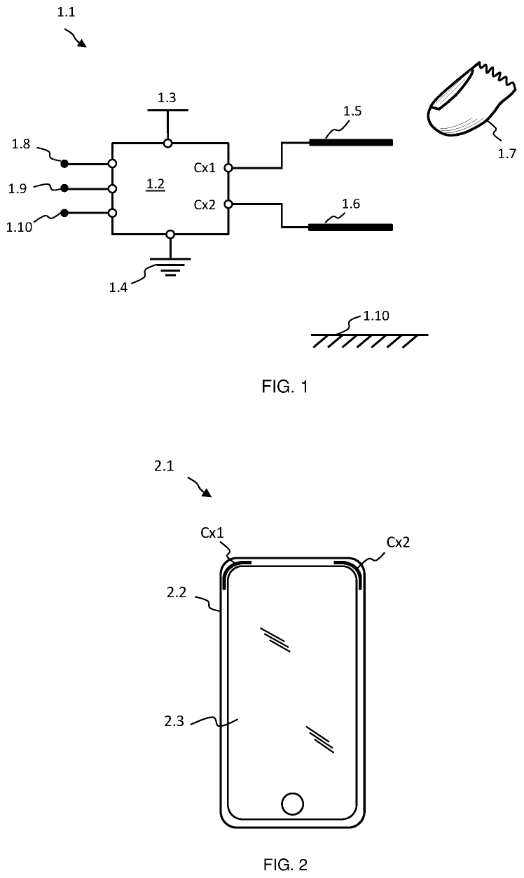

FIG. 1 presents an exemplary embodiment of the present invention at 1.1, wherein an integrated capacitive sensing circuit 1.2 may perform both self-C and mutual-C measurements using electrodes 1.5 and 1.6, with mutual-C values which may be used to detect proximity of a user 1.7 and self-C values to detect user touch. The circuit 1.2 is powered from a positive supply 1.3 and is connected to circuit ground 1.4. Various connections 1.8 to 1.10 are made to the circuit 1.2, for example communication lines, control lines, digital input/output pins and so forth.

The circuit 1.2 may automatically switch between a mutual-C sensing mode and a self-C sensing mode in a time-divisional manner, or it may switch modes based on the one or other stimulus or input. Self-C measurements may utilize either or both of the electrodes 1.5 and 1.6 to measure capacitance between said electrodes and a local electrical earth 1.10. There may be a varying amount of capacitive coupling between the electrical earth 1.10 and the local circuit ground 1.4.

Mutual-C measurements may be performed by using the electrode 1.5 as a transmitter electrode and the electrode 1.6 as a receiver electrode, or vice versa. According to the present invention, when the electrodes 1.5 and/or 1.6 are located close to ground 1.4, self-C based proximity detection of the user 1.7 may be severely limited in distance, in which case the circuit 1.2, or another circuit, may utilize measured values from either or both self-C and mutual-C measurements to decide to switch to a mutual-C mode and to use mutual-C measurement values for said proximity detection.

FIG. 2 presents an exemplary mobile phone application of the present invention at 2.1, wherein a phone 2.2 comprises capacitive sensing circuitry, not shown, but of the kind depicted in FIG. 1, which embodies the present invention, and which may make both self-C and mutual-C measurements in a time-divisional or other manner using capacitive sensing electrodes Cx1 and Cx2. A screen 2.3 of the phone is located quite close to said electrodes, as shown, and may be viewed as a grounded structure in terms of capacitive sensing. Either or both of the electrodes Cx1 and Cx2 may be used for self-C measurements. For mutual-C measurements, the electrode Cx1 is used a transmitter electrode and Cx2 as a receiver electrode, or vice versa. Typical applications of the capacitive sensing in said phone may include on-ear detection, Specific Absorption Rate (SAR) related measurements or left/right hand grip detection. In some embodiments, the electrode Cx1 may also function as an LTE antenna, with a high parasitic capacitance, and the electrode Cx2 may function as a Wi-Fi or GPS antenna.

Due to the nearness of screen or grounded structure 2.3, mutual-C measurements with the electrodes Cx1 and Cx2 may be used by said capacitive sensing circuit (not shown) to detect proximity of a user, as self-C capacitance based proximity detection distance may be limited. The capacitive sensing circuit (not shown) may use self-C measurements with either or both of the electrodes Cx1 and Cx2 to detect when the phone is located very close to the user's body, for example for on-ear detection. The sensing circuit may also utilize measurement values obtained with the electrodes Cx1 and Cx2 during a self-C mode to determine when and how to reseed, reset or adjust a reference value or decision thresholds used for mutual-C measurements with said electrodes, or vice versa.

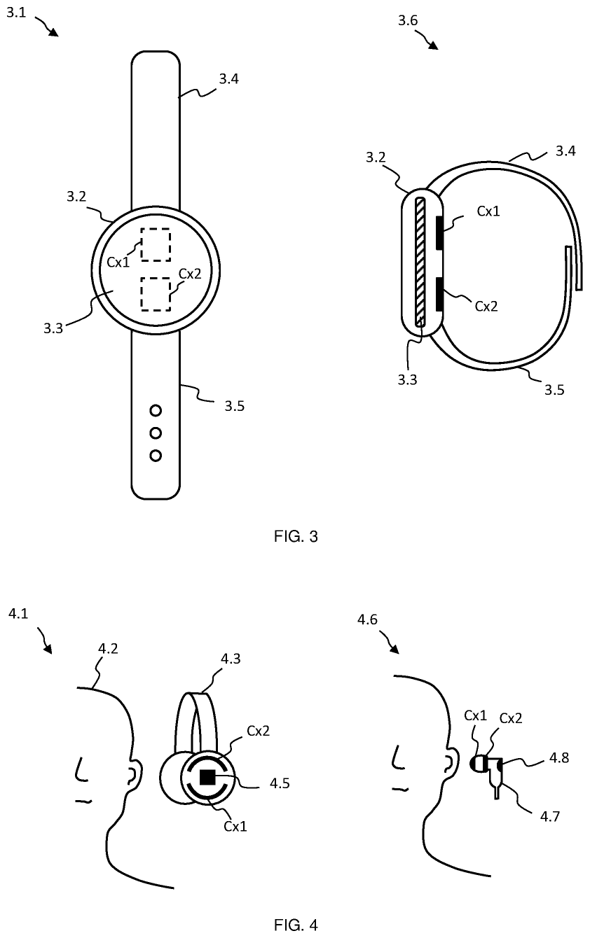

In wearable consumer electronic products, for example in a watch or activity band 3.2 as shown at 3.1 in FIG. 3, grounded structures 3.3 are located very close to electrodes Cx1 and Cx2 used for capacitive sensing. This may adversely influence self-C measurements performed with the electrodes, especially in terms of proximity detection distance. Due to the nature of watches and activity bands, these are often worn loosely around a user's wrist using straps 3.4 and 3.5 (for example), necessitating the use of proximity measurements. According to the present invention, a combination of mutual-C and self-C measurements by a capacitive sensing circuit 1.2, not shown in FIG. 3 but included in a case of the watch or band 3.2 may be used to determine the wear case, and to decide when to utilize mutual-C measurements with the electrodes Cx1 and Cx2 to detect user proximity over a longer distance than what may be possible via self-C measurements with either or both of the electrodes Cx1 and Cx2. As before, self-C measurement values can be used to determine when to reseed, restart or adjust a reference value or decision thresholds used for mutual-C measurements, or vice versa.

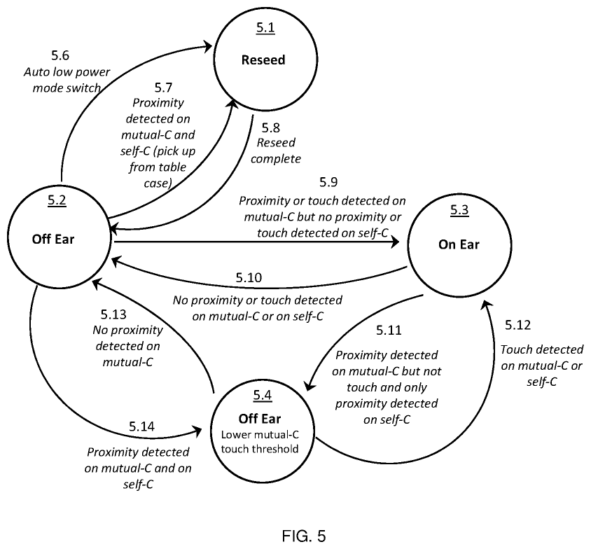

FIG. 4 depicts yet another exemplary consumer electronic embodiment of the present invention, for personal audio devices. Over-ear headphones 4.3 for a user 4.2 is shown at 4.1, with said headphones 4.3 comprising a capacitive sensing circuit 1.2 (not shown) which embodies the present invention, and which performs both self-C and mutual-C measurements with electrodes Cx1 and Cx2 in a time-divisional, alternating or other manner. Due to the nature of over-ear headphones usage, the headphones often shift position. This may necessitate the use of proximity sensing. However, as space is at a premium in such products, a grounded structure, as shown in exemplary manner at 4.5 is often located quite close to the sensing electrodes Cx1 and Cx2, making the use of self-C based proximity detection, as is conventionally used in the art, impractical. Accordingly, the present invention teaches that said capacitive sensing circuit 1.2 (not shown) or another circuit, may perform proximity measurements based on mutual-C values, and may use measurements from either or both self-C and mutual-C modes to determine when to switch modes, or how and when to adjust the present capacitive sensing mode or the other capacitive sensing mode, or both.

A related embodiment is shown at 4.6, wherein in-ear headphones or earphones 4.7 utilize a capacitive sensing circuit 1.2, not shown, as well as capacitive sensing electrodes Cx1 and Cx2, to perform both self-C and mutual-C measurements in a time-divisional, alternating or other manner, similar to that taught elsewhere in the present disclosure. In such devices, space is severely limited, leading to very small capacitive sensing electrodes Cx1 and Cx2 as well as small ground reference conducting structures, as shown at 4.8. To ensure reliable user proximity, touch, pick-up, insertion and release detection, the apparatus and methods as taught by the present invention may need to be utilized.

For example, a state-diagram for ear- or headphone detection is presented in FIG. 5. The diagram is largely self-explanatory, but will be explained briefly. When earphones are off-ear, as at state 5.2, a low power mode switch may cause a transition 5.6 to a reseed state 5.1 and a return 5.8 to the off-ear state 5.2 when the reseeding is complete. When both mutual-C and self-C measurements detect a user's proximity, as at 5.7, the capacitive sensing circuit, or another circuit, may discern that reseeding is required, for example due to a pick-up event, resulting in transition to and from the reseed state 5.1.

When the earphones are in the off-ear state 5.2, and both proximity and touch are detected via mutual-C measurements, but not via self-C measurements, a transition 5.9 is made to an on-ear state 5.3. The state diagram returns from the on-ear state 5.3 to the off-ear state 5.2 via a transition 5.10 when no proximity or touch is detected via mutual-C and no proximity or touch is detected via self-C measurements.

When the earphones are in the off-ear state 5.2, and proximity is detected via mutual-C and self-C measurements, a transition 5.14 to a second off-ear state 5.4 with a lower mutual-C touch threshold is made. Once proximity is not detected via mutual-C measurements any more, the system returns via a transition 5.13 to the off-ear state 5.2.

From the second off-ear state 5.4, a touch detected via mutual-C or self-C may cause the system to transition via 5.12 to the on-ear state 5.3, with a return to the second off-ear state 5.4 via a transition 5.11 if only proximity and not touch is detected via mutual-C and self-C measurements. As is evident, the system may also return from the on-ear state 5.3 to the off-ear state 5.2 via the transition 5.10 after moving from the state 5.4 to the state 5.3.

1.-10. (canceled)

11. A capacitive sensing circuit comprising first and second sensing electrodes, self-capacitance measurement circuitry and mutual-capacitance measurement circuitry, wherein said sensing circuit utilize both self-capacitance sensing and mutual-capacitance sensing to optimally detect an engaging object via said electrodes, said detection comprising use of mutual-capacitance measurements, using both the first and second electrodes, for proximity detection over a first distance and use of self-capacitance measurements, using said first sensing electrode(s), said second sensing electrode(s) or both said first and second sensing electrodes, for detection over a second distance, wherein said first distance is substantially larger than said second distance.

12. The circuit of claim 11, wherein grounded structures close to said electrode(s) in a mobile electronic product containing said circuit substantially limit proximity detection distance with self-capacitance measurements.

13. The circuit of claim 11 wherein said object is a human body part.

14. The circuit of claim 12 wherein said mobile electronic product is at least one product selected from the group consisting of an activity band or watch, a mobile phone, a tablet computer and a headphone or earphone.

15. The circuit of claim 12, wherein said grounded structures comprise at least one of a battery of said mobile product, a screen of said mobile product, a printed circuit board conductor or other grounded conductive structures in said product.

16. The circuit of claim 11, wherein said mutual-capacitance measurements are used to detect object proximity over the first distance, wherein said self-capacitance measurements are used to detect object proximity or touch over the second distance and wherein a combination of said mutual-capacitance and self-capacitance measurements are used to detect object proximity or touch over a third distance, with said third distance less than said second distance.

17. The circuit of claim 14, wherein said product is a mobile phone and wherein mutual-capacitance measurements are used to detect user proximity to the mobile phone, facilitating a decision when to switch a screen of the mobile phone off, with said self-capacitance measurements used to detect when the mobile phone is on-ear.

18. The circuit of claim 17, wherein the sensing electrodes are also used as radio frequency antennas for communication.

19. The circuit of claim 14, wherein said product is an activity band or watch, wherein the mutual-capacitance measurements are used to detect proximity when a band of the activity band or watch is fastened loosely, and wherein the self-capacitance measurements are used to detect user touch or proximity when said band is fastened tightly.

20. The circuit of claim 11 comprising an additional sensing channel used for reference measurements to compensate for at least one of temperature, noise and time, wherein the additional reference channel is not substantially influenced by said engaging object.

21. The circuit of claim 11, wherein a decrease in said first proximity detection distance is used to either trigger or release a proximity detection event based on the self-capacitance measurements.

22. The circuit of claim 11, wherein both the mutual-capacitance and self-capacitance measurements are used to identify when a device comprising said circuit is picked up from a surface.

23. The circuit of claim 14, wherein said product is a headphone or an earphone, and wherein detection of a user proximity event via both said mutual-capacitance and self-capacitance measurements is used to determine that the product is picked up by said user.

24. The circuit of claim 23, wherein detection of a user proximity or touch event via said mutual-capacitance measurements but not via said self-capacitance measurements is used to determine that the product is placed on or in ears of said user.

25. The circuit of claim 24, wherein detection of a user proximity event via both said mutual-capacitance and said self-capacitance measurements without detecting a user touch event via said measurements is used to determine that the product has been removed from or out of the ears of said user.

26. The circuit of claim 11, wherein values obtained during said self-capacitance measurements are used to determine when to change a reference value used during said mutual-capacitance measurements and wherein said change uses subsequent mutual-capacitance measured values.

27. The circuit of claim 11, wherein said self-capacitance measurement values are used to determine the baseline of reference values for subsequent mutual-capacitance measurements.

28. The circuit of claim 11, wherein said self-capacitance measurement values are used to determine thresholds for proximity or touch events discerned during subsequent mutual-capacitance measurements.

29. The circuit of claim 11, wherein mutual-capacitance measurement values are used to reseed, adjust and/or reset subsequent self-capacitance measurements.
